(19) United States
(12) Patent Application Publication
(10) Pub. No.: US 2024/0006481 A1
(43) Pub. Date: Jan. 4, 2024

(54) ALTERNATING SACRIFICIAL LAYER MATERIALS FOR MECHANICALLY STABLE 2D NANORIBBON ETCH

(71) Applicant: Intel Corporation, Santa Clara, CA (US)

(72) Inventors: Chelsey DOROW, Portland, OR (US); Kevin P. O'BRIEN, Portland, OR (US); Sudarat LEE, Hillsboro, OR (US); Ande KITAMURA, Portland, OR (US); Ashish Verma PENUMATCHA, Beaverton, OR (US); Carl H. NAYLOR, Portland, OR (US); Kirby MAXEY, Hillsboro, OR (US); Chia-Ching LIN, Portland, OR (US); Scott B. CLENDENNING, Portland, OR (US); Uygar E. AVCI, Portland, OR (US)

(21) Appl. No.: 17/853,547

(22) Filed: Jun. 29, 2022

(51) Int. Cl. H01L 29/06; H01L 29/423; H01L 29/66; H01L 29/786

(52) U.S. Cl. CPC H01L 29/0673; H01L 29/42392; H01L 29/6681; H01L 29/66545; H01L 29/78696

(57) ABSTRACT

Embodiments disclosed herein include transistors and methods of forming transistors. In an embodiment, the transistor comprises a source region, a drain region, a first semiconductor channel between the source region and the drain region, and a second semiconductor channel between the source region and the drain region over the first semiconductor channel. In an embodiment, an insulator is around the source region, the drain region, the first semiconductor channel, and the second semiconductor channel. In an embodiment, a first access hole is in the insulator adjacent to a first edge of the first semiconductor channel, and a second access hole is in the insulator adjacent to a second edge of the first semiconductor channel.

### TECHNICAL FIELD

Embodiments of the disclosure are in the field of semiconductor structures and processing and, in particular, to alternating sacrificial layers that are etch selective to each other in order to provide mechanical support for 2D nanoribbon transistor architectures.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and currently known fabrication processes may limit the possibility to further extend them into the 10 nanometer node or sub-10 nanometer node range. Consequently, fabrication of the functional components needed for future technology nodes may require the introduction of new methodologies or the integration of new technologies in current fabrication processes or in place of current fabrication processes.

In the manufacture of integrated circuit devices, multi-gate transistors, such as tri-gate transistors and gate-all-around (GAA) transistors, have become more prevalent as device dimensions continue to scale down. Tri-gate transistors and GAA transistors are generally fabricated on either bulk silicon substrates or silicon-on-insulator substrates. In some instances, bulk silicon substrates are preferred due to their lower cost and compatibility with the existing high-yielding bulk silicon substrate infrastructure.

Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

### BRIEF DESCRIPTION OF THE DRAWINGS

FIG. 1A is a cross-sectional illustration of a transistor device at a stage of manufacture, in accordance with an embodiment.

FIG. 1B is a cross-sectional illustration of the transistor device after the sacrificial layers are removed, in accordance with an embodiment.

FIG. 1C is a cross-sectional illustration of the transistor device after the gate stack is formed around the channels, in accordance with an embodiment.

FIG. 2A is a cross-sectional illustration of a transistor device with first sacrificial layers and second sacrificial layers, in accordance with an embodiment.

FIG. 2B is a cross-sectional illustration of the transistor device after the first sacrificial layers are removed, in accordance with an embodiment.

FIG. 2C is a cross-sectional illustration of the transistor device after a portion of the gate stack is formed around the channels, in accordance with an embodiment.

FIG. 2D is a cross-sectional illustration of the transistor device after the second sacrificial layers are removed, in accordance with an embodiment.

FIG. 2E is a cross-sectional illustration of the transistor device after the remainder of the gate stack is formed around the channels, in accordance with an embodiment.

FIG. 3 is a cross-sectional illustration of a transistor device with remnants of a first sacrificial layer and a second sacrificial layer, in accordance with an embodiment.

FIG. 4 is a perspective view illustration of a transistor device, in accordance with an embodiment.

FIG. 5A is a cross-sectional illustration of the transistor device with first sacrificial layers and second sacrificial layers, in accordance with an embodiment.

FIG. 5B is a cross-sectional illustration of the transistor device after a first opening is formed and first sacrificial layers are removed, in accordance with an embodiment.

FIG. 5C is a cross-sectional illustration of the transistor device after a first portion of the gate stack is provided around the channels, in accordance with an embodiment.

FIG. 5D is a cross-sectional illustration of the transistor device after a second opening is formed and second sacrificial layers are removed, in accordance with an embodiment.

FIG. 5E is a cross-sectional illustration of the transistor device after a second portion of the gate stack is provided around the channels, in accordance with an embodiment.

FIG. 6 illustrates a computing device in accordance with one implementation of an embodiment of the disclosure.

FIG. 7 is an interposer implementing one or more embodiments of the disclosure.

### DESCRIPTION OF THE EMBODIMENTS

Embodiments described herein comprise alternating sacrificial layers that are etch selective to each other in order to provide mechanical support for 2D nanoribbon transistor architectures. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Transition metal dichalcogenides (TMDs) have been an area of investigation in order to continue scaling transistor devices to smaller process nodes. For example, TMD channels enable aggressive scaling of channel length to below 10 nm. The use of TMDs for the channel is not without issue. Primarily, it has been shown that the TMD channels are susceptible to mechanical damage due to their thin, layered, nature and may be damaged during channel release and gate stack deposition processes. That is, the TMD channels (which may be only one monolayer or several monolayers thick) are unsupported along their length between the source region and the drain region. Without support, the capillary forces may act on the channels and cause damage or otherwise non-functional transistors. As such, it is difficult to form vertical stacks of multiple TMD channels.

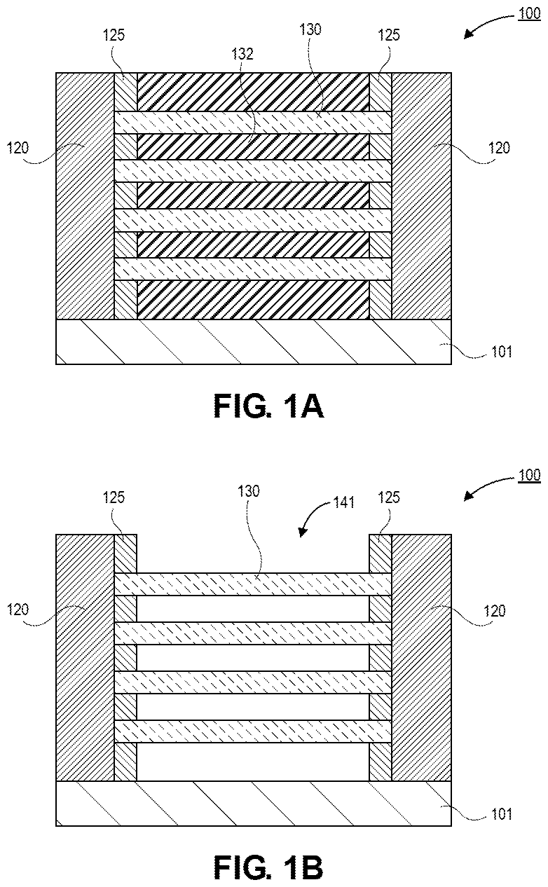

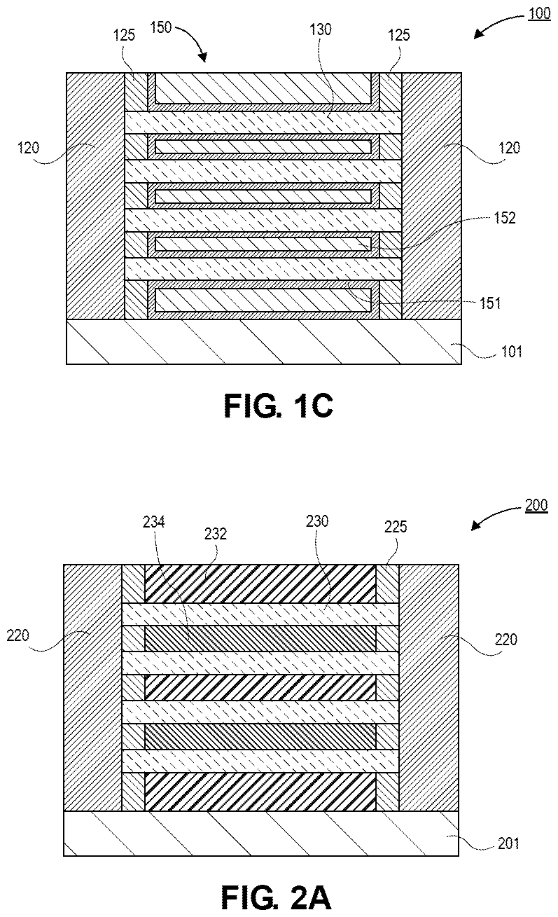

An example, of such a process is shown in FIGS. 1A-1C. In FIG. 1A, a transistor device 100 includes source/drain regions 120 that are provided on opposite ends of semiconductor channels 130 that are formed over a substrate 101. The channels 130 may be nanoribbon or nanowire channels. For example, the semiconductor channels 130 may be TMD material. The channels 130 are supported from above and below by a sacrificial layer 132. Spacers 125 may be outside of the sacrificial layer 132, and the channels 130 pass through the spacers 125.

Referring now to FIG. 1B, a cross-sectional illustration of the transistor device 100 after the sacrificial layers 132 are removed to form openings 141 is shown. The removal of the sacrificial layers 132 may be done with an etching process that does not significantly attack the channels 130. As shown, the channels 130 have a relatively long span between the source/drain regions 120. Due to their small thickness (in the vertical direction of FIG. 1), the channels 130 are susceptible to mechanical damage. For example, capillary forces from the etchant may bend, break, stress, strain, delaminate, or otherwise damage the channels 130. In some instances, adjacent channels 130 may be brought into contact with each other. Then, in FIG. 1C, a gate stack 150 is applied around the channels 130. The gate stack 150 may include a gate dielectric 151 and a gate metal 152. In cases with damaged channels 130, the gate stack 150 may be improperly formed and lead to non-working or defective transistors 100.

Accordingly, embodiments disclosed herein include a process that provides constant support to the semiconductor channels. This is done by providing a pair of sacrificial layers. The first sacrificial layers and the second sacrificial layers are alternated with each other. Additionally, the sacrificial layers are etch selective to each other. As such, the first sacrificial layers may be etched leaving the second sacrificial layers to support the channels. A first part of the gate stack may then be formed in place of the first sacrificial layers. Then, the second sacrificial layers are removed, and the channels are supported by first portion of the gate stack. The second portion of the gate stack can then be formed in place of the second sacrificial layers. In this way, the channels are mechanically supported through the entire process.

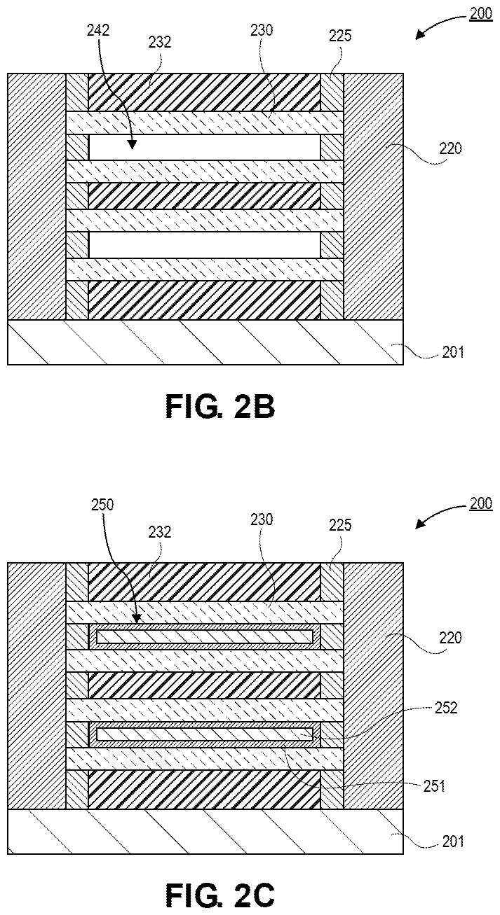

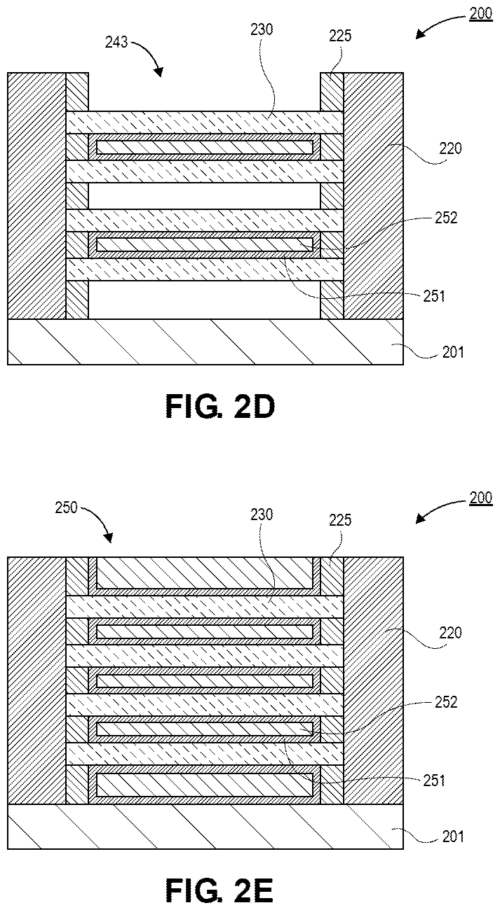

Referring now to FIG. 2A, a cross-sectional illustration of a transistor device 200 is shown, in accordance with an embodiment. In an embodiment, the transistor device 200 is a non-planar transistor device formed over a substrate 201. More particularly, the transistor device 200 may be a gate-all-around (GAA) device. In an embodiment, the transistor device 200 comprises a stack of semiconductor channels 230. For example, four channels 230 are shown in FIG. 2A. Though, it is to be appreciated that any number of channels 230 (e.g., one or more) may be included in the transistor device 200.

In an embodiment, the substrate 201 may comprise any substrate material. In an embodiment, the underlying substrate 201 represents a general workpiece object used to manufacture integrated circuits. In an embodiment, the substrate 201 may comprise a semiconductor substrate 201. The semiconductor substrate 201 often includes a wafer or other piece of silicon or another semiconductor material. Suitable semiconductor substrates 201 include, but are not limited to, single crystal silicon, polycrystalline silicon and silicon on insulator (SOI), as well as similar substrates formed of other semiconductor materials, such as substrates including germanium, carbon, or group III-V materials.

In a particular embodiment, the semiconductor channels 230 may be a transition metal dichalcogenide (TMD) semiconductor material. TMD materials typically take the form of MX₂, where M is transition metal atom (e.g., Mo, W, etc.), and X is a chalcogen atom (e.g., S, Se, or Te). Typically, a layer of M atoms are sandwiched between layers of chalcogen atoms. TMD materials may generally be considered a 2D material. Other 2D semiconductor materials may also be used in some embodiments disclosed herein. The TMD semiconductor material may be a single layer (i.e., a layer of the M atom sandwiched between two X atom layers) or multiple layers thick. The channels 230 may have any form factor. For example, the channels 230 may include nanoribbon channels 230 or nanowire channels 230. A nanoribbon channel refers to a structure that has one confined dimension (e.g., a small thickness compared to a length and a width of the channel), and a nanowire channel refers to a structure that has two confined dimensions (e.g., a small thickness and a small width, compared to a length of the channel). In a particular embodiment, the confined dimension (or dimensions) may have values of approximately 5 nm or smaller, or approximately 1 nm or smaller. As used herein, “approximately” may refer to a range of values that are within ten percent of the stated value. For example, approximately 1 nm may include a range from 0.9 nm to 1.1 nm. The use of TMD semiconductor materials allows for aggressive scaling of the transistor device 200. For example, channel lengths may be approximately 10 nm or smaller.

While TMD material and other 2D semiconductor materials are described in greater detail herein, it is to be appreciated that three dimensional (3D) semiconductor materials may also be used in order to form the transistor device 200. For example, the channels 230 may comprise silicon, silicon germanium, or the like.

In an embodiment, the channels 230 may pass through a pair of spacers 225. The ends of the channels 230 may be substantially coplanar with the outer surfaces of the spacers 225. In an embodiment, the spacers 225 may be any suitable spacer material. In one instance the spacers 225 may comprise silicon, oxygen, and carbon (e.g., SiOC) or aluminum and oxygen (e.g., a-Al₂O₃). In an embodiment, source/drain regions 220 may be provided on outside surfaces of the spacers 225. In an embodiment, the source/drain regions 220 may include contact metals, such as tungsten, other metals, or other alloys. In other embodiments, the source/drain regions 220 may comprise epitaxially grown material, such as a metallic phase of the TMD channel. In an embodiment, the source/drain regions 220 may comprise metallic phase TMD material and contact metals. As used herein source/drain regions 220 may refer to either a source region or a drain region. That is, source/drain regions 220 are not both a source region and a drain region. For example, in FIG. 2A, the source/drain region 220 on the left may be a source region, and the source/drain region 220 on the right may be a drain region.

In an embodiment, sacrificial layers 234 and 232 may be provided around the channels 230. Particularly, first sacrificial layers 234 and second sacrificial layers 232 may be provided in an alternating pattern around the channels 230. For example, a second sacrificial layer 232 may be below a bottommost channel 230 and a first sacrificial layer 234 may be provided over the bottommost channel 230. That is, each channel 230 may be contacted by both a first sacrificial layer 234 and a second sacrificial layer 232. As such, the sacrificial layers 234 and 232 can be selectively removed while maintaining mechanical support to the channels 230, as will be described in greater detail below. The first sacrificial layers 234 and the second sacrificial layers 232 may be etch selective to each other. This allows for a first etchant to be used to remove the first sacrificial layers 234 without also removing the second sacrificial layers 232.

Referring now to FIG. 2B, a cross-sectional illustration of the transistor 200 after the first sacrificial layers 234 are removed is shown, in accordance with an embodiment. In an embodiment, the first sacrificial layers 234 may be removed with a first etching process. The first etching process may include an etchant chemistry that leaves the second sacrificial layers 232 substantially unaltered. Removing the first sacrificial layers 234 results in openings 242 being formed between the channels 230. The openings 242 result in one surface (top or bottom) of each channel 230 being exposed. However, it is to be appreciated that each of the channels 230 remain mechanically supported by the second sacrificial layers 232. As such, capillary forces do not damage the channels 230.

Referring now to FIG. 2C, a cross-sectional illustration of the transistor device after a first portion of the gate stack 250 is formed is shown, in accordance with an embodiment. In an embodiment, the first portion of the gate stack 250 may be formed in the openings 242 between the channels 230. That is, the first portion of the gate stack 250 may replace the volume previously occupied by the first sacrificial layers 234. In an embodiment, the gate stack 250 may comprise a gate dielectric 251 and a gate metal 252.

In an embodiment, the gate metal 252 may include a workfunction metal and a fill metal. When the workfunction metal will serve as an N-type workfunction metal, the gate metal 252 preferably has a workfunction that is between about 3.9 eV and about 4.2 eV. N-type materials that may be used to form the gate metal 252 include, but are not limited to, hafnium, zirconium, titanium, tantalum, aluminum, and metal carbides that include these elements, i.e., titanium carbide, zirconium carbide, tantalum carbide, hafnium carbide and aluminum carbide. When the workfunction metal will serve as a P-type workfunction metal, the gate metal 252 preferably has a workfunction that is between about 4.9 eV and about 5.2 eV. P-type materials that may be used to form the gate metal 252 include, but are not limited to, ruthenium, palladium, platinum, cobalt, nickel, and conductive metal oxides, e.g., ruthenium oxide.

The gate dielectric 251 may be, for example, any suitable oxide such as silicon dioxide or high-k gate dielectric materials. Examples of high-k gate dielectric 251 materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Referring now to FIG. 2D, a cross-sectional illustration of the transistor 200 after the second sacrificial layers 232 are removed is shown, in accordance with an embodiment. In an embodiment, the second sacrificial layers 232 may be removed with an etching process that does not substantially alter the gate stack 250. Removal of the second sacrificial layers 232 results in openings 243 being formed. The openings 243 allow for surfaces (either top or bottom) of the channels 230 to be exposed. However, since the gate stack 250 is still present, the channels 230 remain mechanically supported. As such, capillary forces do not damage the channels 230.

Referring now to FIG. 2E, a cross-sectional illustration of the transistor 200 after the second portion of the gate stack 250 is formed is shown, in accordance with an embodiment. In an embodiment, the gate stack 250 may fill the openings 243 formed by the removal of the second sacrificial layers 232. The gate stack 250 may include a gate dielectric 251 and a gate metal 252. The gate dielectric 251 and the gate metal 252 may be substantially similar to the gate dielectric 251 and the gate metal 252 formed in the openings 242. Accordingly, gate metal 252 is provided around the channels 230. In the illustrated view, the gate metal 252 is above and below each of the channels 230. However, it is to be appreciated that the gate metal 252 may also wrap around sides of the channels 230 (into and out of the plane of FIG. 2E) in order to provide gate-all-around (GAA) control of the channels 230.

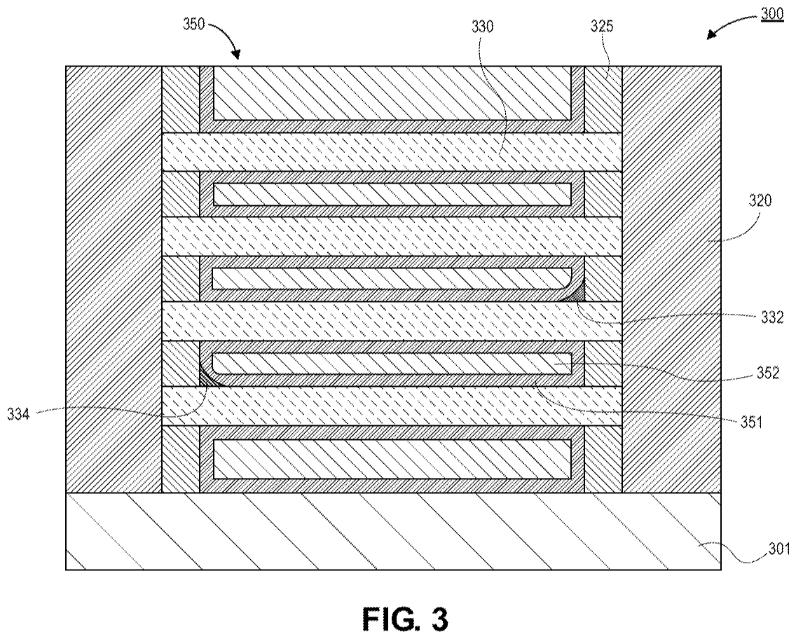

Referring now to FIG. 3, a cross-sectional illustration of a transistor 300 is shown, in accordance with an embodiment. The transistor 300 may include a substrate 301. A stack of channels 330 may be provided over the substrate 301. The channels 330 may pass through spacers 325 to contact source/drain regions 320. In an embodiment, a gate stack 350 is provided around the channels 330 within the spacers 325. For example, the gate stack 350 may include a gate dielectric 351 and a gate metal 352.

As shown in FIG. 3, residual portions of the sacrificial layers 334 and 332 may be provided between the channels 330. In a particular embodiment, the first sacrificial layer 334 is a different material than the second sacrificial layer 332. Residual portions may remain due to incomplete etching of the sacrificial layers in previous operations. As shown, only a single type of the residual sacrificial layers 334 and 332 is provided between a given pair of channels 330. For example, residual portions of the first sacrificial layer 334 are provided between the bottommost channel 330 and the second channel 330, and residual portions of the second sacrificial layer 332 are provided between the second channel 330 and the third channel 330.

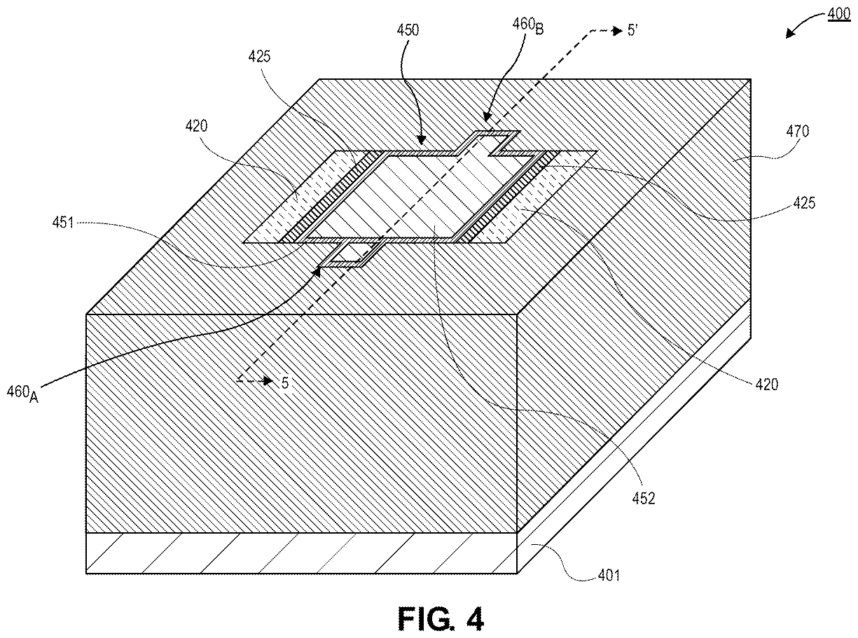

Referring now to FIG. 4 is a perspective view illustration of a transistor 400 is shown, in accordance with an embodiment. In an embodiment, the transistor 400 is formed over a substrate 401. An insulating layer 470 may be provided around the channels (not shown), the source/drain regions 420, the spacers 425, and the gate stack 450. FIG. 4 illustrates access holes 460_{A} and 460_{B} that are provided along sides of the channels. The access holes 460_{A} and 460_{B} may be formed into the insulating layer 470 and provide access to the sacrificial layers that are removed with etching processes. After the sacrificial layers are removed, the access holes 460_{A} and 460_{B} may be filled with the materials of the gate stack 450 (i.e., the gate dielectric 451 and the gate metal 452.

The access holes 460_{A} and 460_{B} are formed with separate patterning and etching processes. As such, there will generally be some degree of misalignment between the first access hole 460_{A} and the second access hole 460_{B}. For example, the second access hole 460_{B} may be shifted over (e.g., shifted towards the source/drain region 420 on the right) compared to the first access hole 460_{A}. In an embodiment, the offset between the access hole 460_{A} and the access hole 460_{B} may be 1 nm or more. Though, smaller offsets may also be possible depending on the patterning processes used to form the access holes 460. In addition to having an offset with each other, the size and/or shape of the offset holes 460_{A} and 460_{B} may be different from each other.

While referred to as “access holes”, it is to be appreciated that the hole is through the insulating layer 470. The structure that fills the access holes (i.e., the gate dielectric 451 and the gate metal 452) may sometimes be referred to as extensions of the gate stack 450. That is, the extensions may extend out laterally away from the edges of the channels of the transistor 400.

In the embodiment shown in FIG. 4, the first access hole 460_{A} and the second access hole 460_{B} may have different architectures. For example, access hole 460_{A} has a gate dielectric layer 451 that lines an entire perimeter of the gate metal 452, whereas the gate dielectric layer 451 of the access hole 460_{B} only lines a partial perimeter of the gate metal 452. In other embodiments, the gate dielectric layer 451 may be similar for both the first access hole 460_{A} and the second access hole 460_{B}.

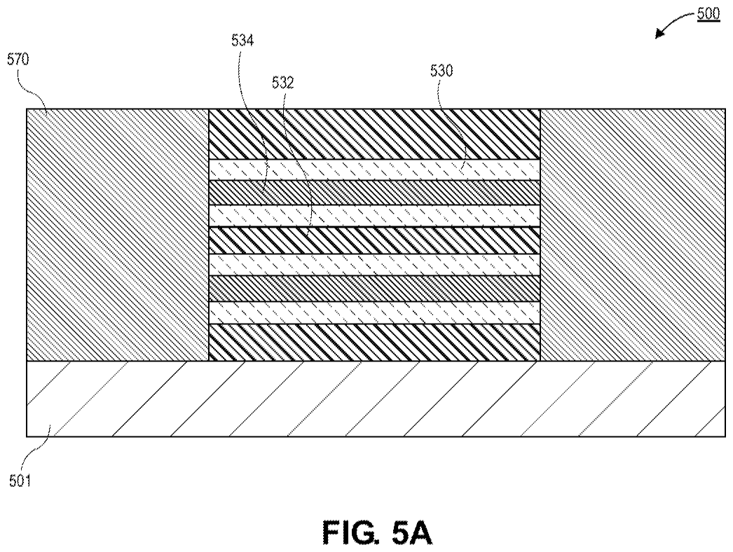

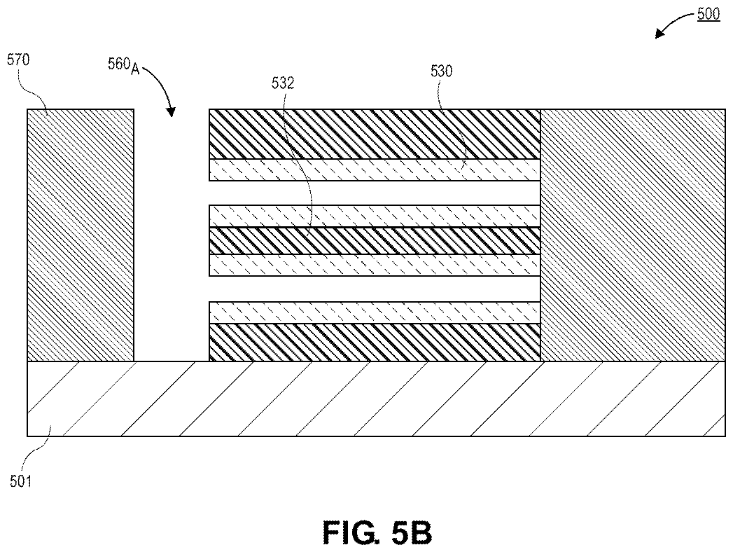

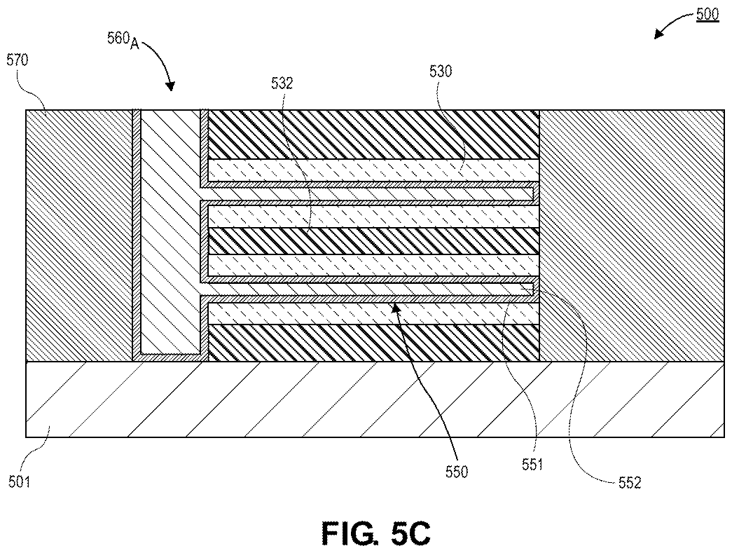

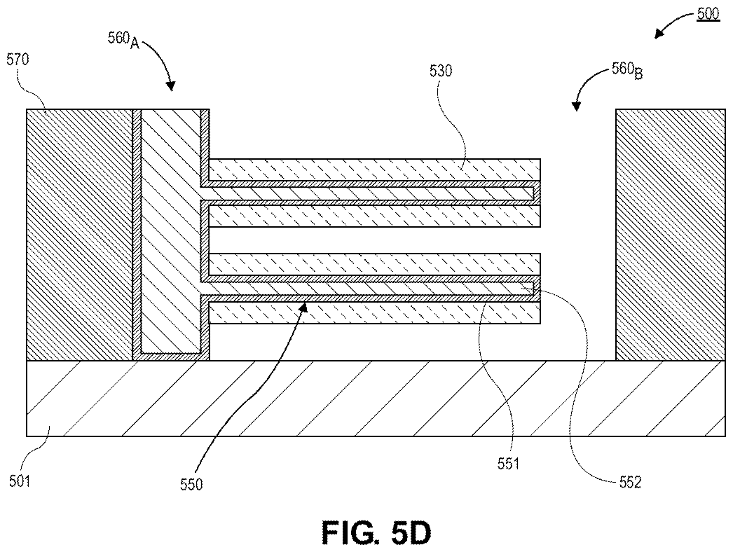

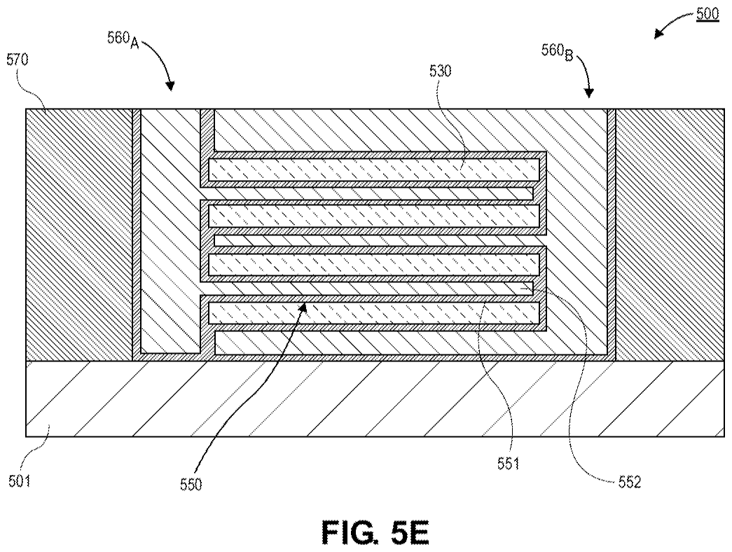

Referring now to FIGS. 5A-5E, a series of cross-sectional illustrations of the transistor 500 at various stages of manufacture is shown, in accordance with an embodiment. The plane illustrated in FIGS. 5A-5E is the plane of line 5-5′ in FIG. 4.

Referring now to FIG. 5A, a cross-sectional illustration of the transistor 500 at a stage of manufacture is shown, in accordance with an embodiment. In an embodiment, the transistor 500 may comprise a substrate 501, such as a silicon substrate or the like. In an embodiment, a stack of channels 530 are provided above the substrate 501. The ends of the channels 530 may contact an insulator layer 570. Additionally, sacrificial layers 534 and 532 may be provided between the channels 530. For example, first sacrificial layers 534 and second sacrificial layers 532 may be provided in an alternating pattern around the channels 530. The first sacrificial layers 534 may be a different material than the second sacrificial layers 532. For example, the first sacrificial layers 534 may be etch selective to the second sacrificial layers 532.

Referring now to FIG. 5B, a cross-sectional illustration of the transistor 500 after a first access hole 560A is formed and the first sacrificial layers 534 are removed is shown, in accordance with an embodiment. As shown, the first access hole 560A is adjacent to edges of the channels 530. The first access hole 560A provides access to the first sacrificial layers 534 so that they may be etched with an etching chemistry that is selective to the second sacrificial layers 532.

As shown, the channels 530 remain mechanically supported by the second sacrificial layers 532. The channels 530 may also be connected to the source/drain regions and spacers (out of the plane of FIG. 5B). Accordingly, the channels 530 are not as susceptible to capillary forces that may otherwise damage the channels 530.

Referring now to FIG. 5C, a cross-sectional illustration of the transistor 500 after a first portion of the gate stack 550 is formed is shown, in accordance with an embodiment. In an embodiment, the gate stack 550 may comprise a gate dielectric 551 and a gate metal 552. As shown, the gate dielectric 551 and the gate metal 552 may also fill the first access hole 560A. Ends of the channels 530 may also be covered by the gate dielectric 551 in some embodiments.

Referring now to FIG. 5D, a cross-sectional illustration of the transistor 500 after a second access hole 560B is formed is shown, in accordance with an embodiment. The second access hole 560B may be formed on the opposite side of the channels 530 from the first access hole 560A. The second access hole 560B provides access to remove the second sacrificial layers 532 with an etching process. After removal of the second sacrificial layers 532, the channels 530 remain supported by the gate stack 550, the source/drain regions, and the spacers. As such, the channels 530 are not susceptible to capillary forces that may damage the channels 530.

Referring now to FIG. 5E, a cross-sectional illustration of the transistor 500 after a second portion of the gate stack 550 is formed is shown, in accordance with an embodiment. As shown, gate dielectric 551 and gate metal 552 may fill the volume previously occupied by the second sacrificial layers 532. The gate dielectric 551 and the gate metal 552 may also fill the second access hole 560B. Accordingly, the gate stack 550 comprises gate structures around the channels 530 and extensions adjacent to the channels within the first access hole 560A and the second access hole 560B.

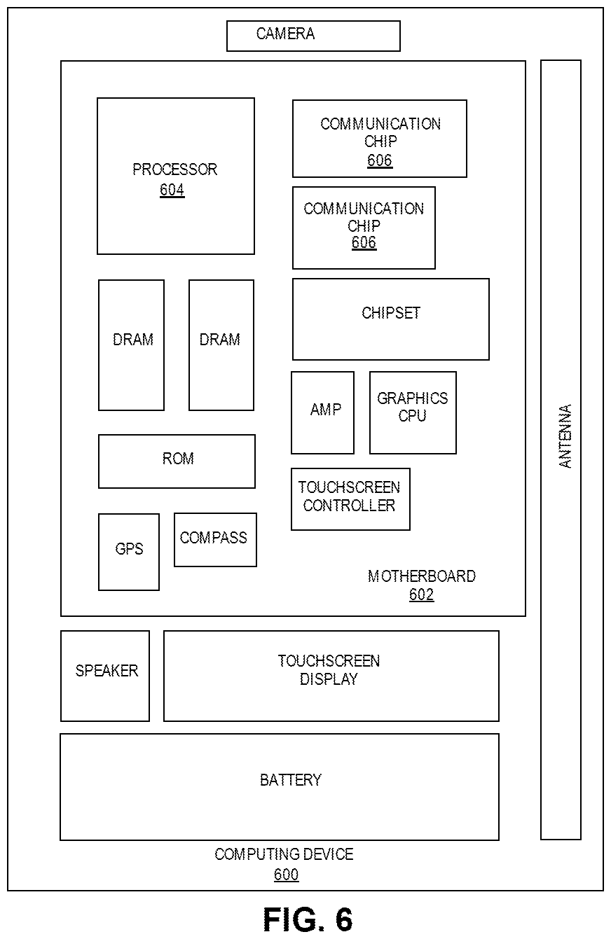

FIG. 6 illustrates a computing device 600 in accordance with one implementation of an embodiment of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In an embodiment, the integrated circuit die of the processor may comprise a transistor device with channels that are mechanically supported throughout the manufacturing process, as described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In an embodiment, the integrated circuit die of the communication chip may comprise a transistor device with channels that are mechanically supported throughout the manufacturing process, as described herein.

In further implementations, another component housed within the computing device 600 may comprise a transistor device with channels that are mechanically supported throughout the manufacturing process, as described herein.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

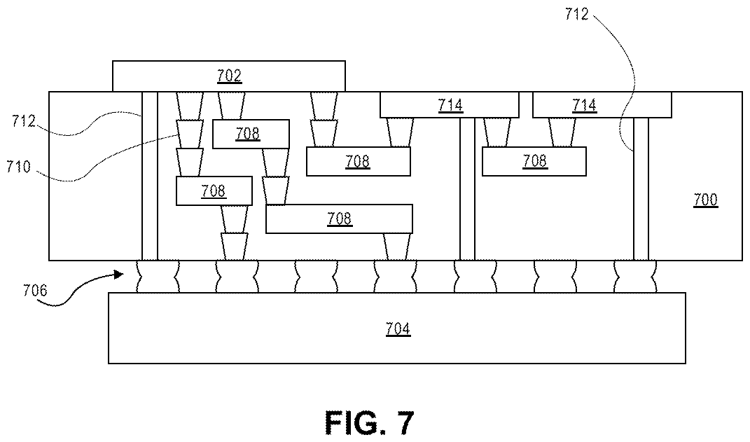

FIG. 7 illustrates an interposer 700 that includes one or more embodiments of the disclosure. The interposer 700 is an intervening substrate used to bridge a first substrate 702 to a second substrate 704. The first substrate 702 may be, for instance, an integrated circuit die. The second substrate 704 may be, for instance, a memory module, a computer motherboard, or another integrated circuit die. In an embodiment, one of both of the first substrate 702 and the second substrate 704 may comprise a transistor device with channels that are mechanically supported throughout the manufacturing process, in accordance with embodiments described herein. Generally, the purpose of an interposer 700 is to spread a connection to a wider pitch or to reroute a connection to a different connection. For example, an interposer 700 may couple an integrated circuit die to a ball grid array (BGA) 706 that can subsequently be coupled to the second substrate 704. In some embodiments, the first and second substrates 702/704 are attached to opposing sides of the interposer 700. In other embodiments, the first and second substrates 702/704 are attached to the same side of the interposer 700. And in further embodiments, three or more substrates are interconnected by way of the interposer 700.

The interposer 700 may be formed of an epoxy resin, a fiberglass-reinforced epoxy resin, a ceramic material, or a polymer material such as polyimide. In further implementations, the interposer 700 may be formed of alternate rigid or flexible materials that may include the same materials described above for use in a semiconductor substrate, such as silicon, germanium, and other group III-V and group IV materials.

The interposer 700 may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 700. In accordance with embodiments of the disclosure, apparatuses or processes disclosed herein may be used in the fabrication of interposer 700.

Thus, embodiments of the present disclosure may comprise a transistor device with channels that are mechanically supported throughout the manufacturing process.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a transistor, comprising: a source region; a drain region; a first semiconductor channel between the source region and the drain region; a second semiconductor channel between the source region and the drain region over the first semiconductor channel; an insulator around the source region, the drain region, the first semiconductor channel, and the second semiconductor channel; a first access hole in the insulator adjacent to a first edge of the first semiconductor channel; and a second access hole in the insulator adjacent to a second edge of the first semiconductor channel.

Example 2: the transistor of Example 1, wherein the first access hole and the second access hole are filled with a dielectric liner and a conductive material.

Example 3: the transistor of Example 1 or Example 2, wherein the first access hole is offset from the second access hole.

Example 4: the transistor structure of Example 3, wherein a sidewall of the first access hole is offset from a sidewall of the second access hole by 1 nm or more.

Example 5: the transistor of Examples 1-4, wherein a shape of the first access hole is different from a shape of the second access hole.

Example 6: the transistor of Examples 1-5, wherein the first semiconductor channel and the second semiconductor channel are nanoribbon channels or nanowire channels.

Example 7: the transistor of Example 6, wherein the first semiconductor channel and the second semiconductor channel comprises a transition metal dichalcogenide (TMD), wherein the TMD takes the form of MX₂, where M is transition metal atom including molybdenum or tungsten, and wherein X is a chalcogen atom including sulfur, selenium, or tellurium.

Example 8: the transistor of Examples 1-7, wherein a remnant of a first sacrificial layer is between the first semiconductor channel and the second semiconductor channel, and wherein a remnant of a second sacrificial layer is above the second semiconductor channel, wherein the first sacrificial layer is etch selective to the second sacrificial layer.

Example 9: a transistor, comprising: a source region; a drain region; a semiconductor channel between the source region and the drain region; and a gate stack over the semiconductor channel, wherein the gate stack comprises a first extension along a first edge of the semiconductor channel and a second extension along a second edge of the semiconductor channel.

Example 10: the transistor of Example 9, wherein the first extension is offset from the second extension.

Example 11: the transistor of Example 10, wherein the first extension is offset from the second extension by 1 nm or more.

Example 12: the transistor of Examples 9-11, wherein a shape of the first extension is different than a shape of the second extension.

Example 13: the transistor of Examples 9-12, wherein the gate stack comprises: a dielectric liner; and a metal over the dielectric liner.

Example 14: the transistor of Example 13, wherein the first extension and the second extension are lined by the dielectric liner and are filled with the metal.

Example 15: the transistor of Examples 9-14, wherein the semiconductor channel is a nanoribbon channel or a nanowire channel.

Example 16: the transistor of Example 15, wherein the semiconductor channel comprises a transition metal dichalcogenide (TMD).

Example 17: the transistor of Examples 9-16, further comprising: a first sacrificial layer remnant above the semiconductor channel; and a second sacrificial layer remnant below the semiconductor channel, wherein the first sacrificial layer remnant is etch selective to the second sacrificial layer remnant.

Example 18: a method of forming a transistor, comprising: providing a plurality of semiconductor channels in a stack, wherein first sacrificial layers and second sacrificial layers are provided between the plurality of semiconductor channels; removing the first sacrificial layers with a first etching chemistry that leaves the second sacrificial layers; forming a first gate stack in the place of the first sacrificial layers; removing the second sacrificial layers with a second etching chemistry; and forming a second gate stack in the place of the second sacrificial layers.

Example 19: the method of Example 18, wherein the first sacrificial layers and the second sacrificial layers are provided in an alternating pattern.

Example 20: the method of Example 18 or Example 19, wherein the plurality of semiconductor channels are mechanically supported from above or below at all times.

Example 21: the method of Examples 18-20, wherein the plurality of semiconductor channels comprises a transition metal dichalcogenide (TMD), wherein the TMD takes the form of MX₂, where M is transition metal atom including molybdenum or tungsten, and wherein X is a chalcogen atom including sulfur, selenium, or tellurium.

Example 22: the method of Example 21, wherein the plurality of semiconductor channels comprise transition metal dichalcogenide (TMD) material.

Example 23: an electronic system, comprising: a board; a package substrate coupled to the board; and a die coupled to the package substrate, wherein the die comprises a transistor, wherein the transistor comprises: a first semiconductor channel; a second semiconductor channel over the first semiconductor channel; a first remnant of a first sacrificial layer between the first semiconductor channel and the second semiconductor channel; and a second remnant of a second sacrificial layer under the first semiconductor channel, wherein the first sacrificial layer is different than the second sacrificial layer.

Example 24: the electronic system of Example 23, further comprising: a gate stack around the first semiconductor channel and the second semiconductor channel.

Example 25: the electronic system of Example 24, wherein the gate stack comprises a first extension along a first edge of the first semiconductor channel and a second extension along a second edge of the first semiconductor channel, wherein the first extension is offset from the second extension.

What is claimed is:

1. A transistor, comprising:
a source region;
a drain region;
a first semiconductor channel between the source region and the drain region;
a second semiconductor channel between the source region and the drain region over the first semiconductor channel;
an insulator around the source region, the drain region, the first semiconductor channel, and the second semiconductor channel;
a first access hole in the insulator adjacent to a first edge of the first semiconductor channel; and
a second access hole in the insulator adjacent to a second edge of the first semiconductor channel.

2. The transistor of claim 1, wherein the first access hole and the second access hole are filled with a dielectric liner and a conductive material.

3. The transistor of claim 1, wherein the first access hole is offset from the second access hole.

4. The transistor structure of claim 3, wherein a sidewall of the first access hole is offset from a sidewall of the second access hole by 1 nm or more.

5. The transistor of claim 1, wherein a shape of the first access hole is different from a shape of the second access hole.

6. The transistor of claim 1, wherein the first semiconductor channel and the second semiconductor channel are nanoribbon channels or nanowire channels.

7. The transistor of claim 6, wherein the first semiconductor channel and the second semiconductor channel comprises a transition metal dichalcogenide (TMD), wherein the TMD takes the form of MX₂, where M is transition metal atom including molybdenum or tungsten, and wherein X is a chalcogen atom including sulfur, selenium, or tellurium.

8. The transistor of claim 1, wherein a remnant of a first sacrificial layer is between the first semiconductor channel and the second semiconductor channel, and wherein a remnant of a second sacrificial layer is above the second semiconductor channel, wherein the first sacrificial layer is etch selective to the second sacrificial layer.

9. A transistor, comprising:
a source region;
a drain region;
a semiconductor channel between the source region and the drain region; and
a gate stack over the semiconductor channel, wherein the gate stack comprises a first extension along a first edge of the semiconductor channel and a second extension along a second edge of the semiconductor channel.

10. The transistor of claim 9, wherein the first extension is offset from the second extension.

11. The transistor of claim 10, wherein the first extension is offset from the second extension by 1 nm or more.

12. The transistor of claim 9, wherein a shape of the first extension is different than a shape of the second extension.

13. The transistor of claim 9, wherein the gate stack comprises:
a dielectric liner; and
a metal over the dielectric liner.

14. The transistor of claim 13, wherein the first extension and the second extension are lined by the dielectric liner and are filled with the metal.

15. The transistor of claim 9, wherein the semiconductor channel is a nanoribbon channel or a nanowire channel.

16. The transistor of claim 15, wherein the semiconductor channel comprises a transition metal dichalcogenide (TMD).

17. The transistor of claim 9, further comprising:
a first sacrificial layer remnant above the semiconductor channel; and
a second sacrificial layer remnant below the semiconductor channel, wherein the first sacrificial layer remnant is etch selective to the second sacrificial layer remnant.

18. A method of forming a transistor, comprising:
providing a plurality of semiconductor channels in a stack, wherein first sacrificial layers and second sacrificial layers are provided between the plurality of semiconductor channels;
removing the first sacrificial layers with a first etching chemistry that leaves the second sacrificial layers;
forming a first gate stack in the place of the first sacrificial layers;
removing the second sacrificial layers with a second etching chemistry; and
forming a second gate stack in the place of the second sacrificial layers.

19. The method of claim 18, wherein the first sacrificial layers and the second sacrificial layers are provided in an alternating pattern.

20. The method of claim 18, wherein the plurality of semiconductor channels are mechanically supported from above or below at all times.

21. The method of claim 18, wherein the plurality of semiconductor channels comprise nanowire channels or nanoribbon channels.

22. The method of claim 21, wherein the plurality of semiconductor channels comprises a transition metal dichalcogenide (TMD), wherein the TMD takes the form of MX₂, where M is transition metal atom including molybdenum or tungsten, and wherein X is a chalcogen atom including sulfur, selenium, or tellurium.

23. An electronic system, comprising:
a board;
a package substrate coupled to the board; and
a die coupled to the package substrate, wherein the die comprises a transistor, wherein the transistor comprises:
a first semiconductor channel;
a second semiconductor channel over the first semiconductor channel;
a first remnant of a first sacrificial layer between the first semiconductor channel and the second semiconductor channel; and
a second remnant of a second sacrificial layer under the first semiconductor channel, wherein the first sacrificial layer is different than the second sacrificial layer.

24. The electronic system of claim 23, further comprising:
a gate stack around the first semiconductor channel and the second semiconductor channel.

25. The electronic system of claim 24, wherein the gate stack comprises a first extension along a first edge of the first semiconductor channel and a second extension along a second edge of the first semiconductor channel, wherein the first extension is offset from the second extension.
